(19) United States
(12) Patent Application Publication
(10) Pub. No.: US 2026/0183892 A1
(43) Pub. Date: Jul. 2, 2026

(54) SUBSTRATE POLISHING APPARATUS AND FILM THICKNESS CALCULATING METHOD

(71) Applicant: EBARA CORPORATION, Tokyo (JP)

(72) Inventors: Keita YAGI, Tokyo (JP); Yuta SUZUKI, Tokyo (JP)

(21) Appl. No.: 19/431,227

(22) Filed: Dec. 23, 2025

(30) Foreign Application Priority Data
Dec. 27, 2024 (JP) 2024-231820

(51) Int. Cl. B24B 37/013

(52) U.S. Cl. CPC B24B 37/013

(57) ABSTRACT

An object is to accurately measure thickness of a film, which is an object of polishing, during polishing of a substrate. A substrate polishing apparatus comprises: a polishing table which is provided with an eddy current sensor and constructed to be able to rotate; a polishing head which is arranged to face the polishing table, constructed to be able to rotate, and constructed to allow a substrate to be attached to a surface facing the polishing table; and a controller. The controller is constructed to obtain pieces of waveform data of output signals of the eddy current sensor when the eddy current sensor has passed multiple paths on the substrate; identify, in the multiple paths on the substrate, mutually corresponding multiple points that are in positions at same distances from the center of the substrate; compare values of the output signals of the eddy current sensor obtained at the identified multiple points to thereby find a minimum value; correct the pieces of waveform data based on the found minimum values; and calculate thickness of a film on a surface of the substrate, based on the corrected pieces of waveform data.

### TECHNICAL FIELD

The present invention relates to a substrate polishing apparatus and a film thickness calculating method.

### BACKGROUND ART

There is a CMP (Chemical Mechanical Polishing) apparatus in apparatuses for manufacturing semiconductor devices. A representative CMP apparatus comprises a polishing table to which a polishing pad is attached, and a polishing head to which a substrate is attached. In the representative CMP apparatus, a substrate is polished by supplying a polishing liquid to the polishing pad, and rotating, in the state that the polishing pad and the substrate are in contact with each other, at least one of the polishing table and the polishing head.

### CITATION LIST

### PATENT LITERATURE

PTL 1: Japanese Patent Application Public Disclosure No. 2021-058955

### SUMMARY OF INVENTION

### TECHNICAL PROBLEM

It is possible to use an eddy current sensor for measuring, during polishing of a substrate, thickness of a film which is an object of polishing. The eddy current sensor is installed in a polishing table, for example. The eddy current sensor moves along a path on a surface of a substrate while a polishing table is being rotated, and measures film thickness at respective points on the path (for example, refer to Patent Literature 1). However, in the case that a metal structure, which has been arranged locally in a substrate, exists in addition to a film (a metal film) which is an object of polishing, it becomes difficult, due to an effect therefrom, to accurately measure thickness, that should be measured originally, of the film which is the object of polishing.

### SOLUTION TO PROBLEM

According to an embodiment, a substrate polishing apparatus is provided: wherein the substrate polishing apparatus comprises a polishing table which is provided with an eddy current sensor and constructed to be able to rotate, a polishing head which is arranged to face the polishing table, constructed to be able to rotate, and constructed to allow a substrate to be attached to a surface facing the polishing table, and a controller: and the controller is constructed to obtain pieces of waveform data of output signals of the eddy current sensor when the eddy current sensor has passed multiple paths on the substrate; identify, in the multiple paths on the substrate, mutually corresponding multiple points that are in positions at same distances from the center of the substrate; compare values of the output signals of the eddy current sensor obtained at the identified multiple points to thereby find a minimum value; correct the pieces of waveform data based on the found minimum values; and calculate thickness of a film on a surface of the substrate, based on the corrected pieces of waveform data.

### BRIEF DESCRIPTION OF DRAWINGS

FIG. 1 is a front view of a substrate polishing apparatus according to an embodiment.

FIG. 2 is a cross-sectional schematic view that shows a structure of an example substrate which is an object of polishing by a substrate polishing apparatus.

FIG. 3 is a flow chart that shows an algorithm of a method according to an embodiment of the present invention.

FIG. 4 is a schematic diagram that shows example paths of an eddy current sensor which passes over a substrate.

FIG. 5 shows an example of waveform data.

FIG. 6 is a schematic diagram that is used for explaining multiple points identified in step 306.

FIG. 7 is an explanatory drawing that is used for explaining a correction process in step 310 that is applied to waveform data of output signals of an eddy current sensor.

FIG. 8 is a flow chart that shows an algorithm of a method according to a different embodiment of the present invention.

FIG. 9 shows an example of waveform data that is used for explaining a process in step 806.

### DESCRIPTION OF EMBODIMENTS

In the following description, embodiments of the present invention will be explained with reference to the figures. In the figures that will be explained in the following description, a reference symbol assigned to one component is also assigned to the other component if the other component is the same as or corresponds to the one component, and overlapping explanation of these components will be omitted.

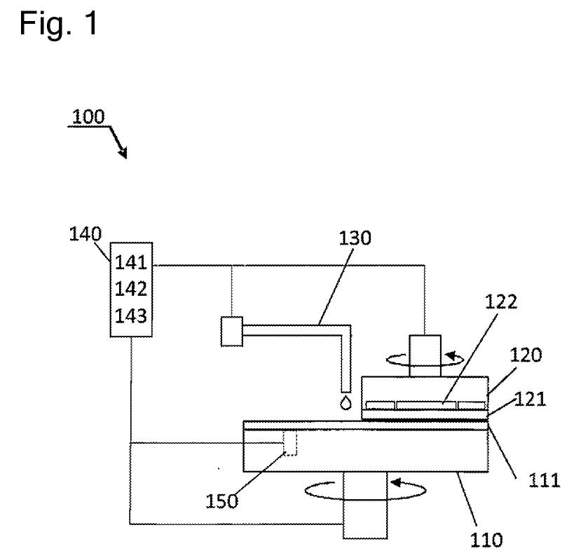

FIG. 1 is a front view of a substrate polishing apparatus 100 according to an embodiment. The substrate polishing apparatus 100 shown in FIG. 1 is a CMP (Chemical Mechanical Polishing) apparatus. It should be reminded that the substrate polishing apparatus 100 is not limited to a CMP apparatus. The substrate polishing apparatus 100 may be any apparatus which polishes a substrate by rotating a polishing table in which an eddy current sensor has been installed.

The CMP apparatus 100 comprises a polishing table 110, a polishing head 120, and a liquid supplying mechanism 130. The CMP apparatus 100 further comprises a controller 140 for controlling respective components. The controller 140 may comprise, for example, a storage device 141, a processor 142, and an input/output device 143.

A polishing pad 111 is installed in an attachable/detachable manner on a top surface of the polishing table 110. In this regard, the top surface of the polishing table 110 refers to a surface, in the polishing table 110, opposite to the polishing head 120. Accordingly, the top surface of the polishing table 110 is not limited to a surface in a position in a vertically upward direction. The polishing head 120 is installed in such a manner that it is in a position opposite to the polishing table 110. A substrate 121 is attached in an attachable/detachable manner to a surface which is in the polishing head 120 and positioned to be opposite to the polishing table 110. The liquid supplying mechanism 130 is constructed to supply a polishing liquid such as slurry or the like to the polishing pad 111. In this regard, the liquid supplying mechanism 130 may be constructed to supply a cleaning liquid, a chemical solution, or the like, in addition to the polishing liquid.

The CMP apparatus 100 is able to bring the substrate 121 into contact with the polishing pad 111, by moving the polishing head 120 downward by operating an up-and-down motion mechanism which is not shown in the figures. In this regard, the up-and-down motion mechanism may be able to move the polishing table 110 upward and downward. The polishing table 110 and the polishing head 120 are rotated by motors or the like which are not shown in the figures. The CMP apparatus 100 polishes the substrate 121 by rotating, in the state that the substrate 121 and the polishing pad 111 are in contact with each other, both the polishing table 110 and the polishing head 120.

The CMP apparatus 100 may further comprise an air bag 122 which is partitioned into multiple concentric circular sections. The air bag 122 may be installed in the polishing head 120. Additionally or alternatively, the air bag 122 may be installed in the polishing table 110. The air bag 122 is a member for adjusting, with respect to each of regions in the substrate 121, a polishing pressure applied to the substrate 121. The air bag 122 is constructed in such a manner that it changes its volume according to the pressure of air introduced into the inside thereof. A fluid other than the air, for example, a nitrogen gas or pure water, may be introduced into the air bag 122.

An eddy current sensor 150 is installed in the inside of the polishing table 110. The eddy current sensor 150 is installed in a position such that the eddy current sensor 150 passes the center of the substrate 121 when the polishing table 110 is rotated during polishing. The eddy current sensor 150 is constructed to induce eddy current in an electrically conductive layer on the surface of the substrate 121. The eddy current sensor 150 is further constructed to output, in response to change in impedance due to a magnetic field generated by the eddy current, a signal corresponding to the thickness of the electrically conductive layer on the surface of the substrate 121. By using the output signal from the eddy current sensor 150, the film thickness of the film, which is the object of polishing, on the surface of the substrate 121 can be obtained.

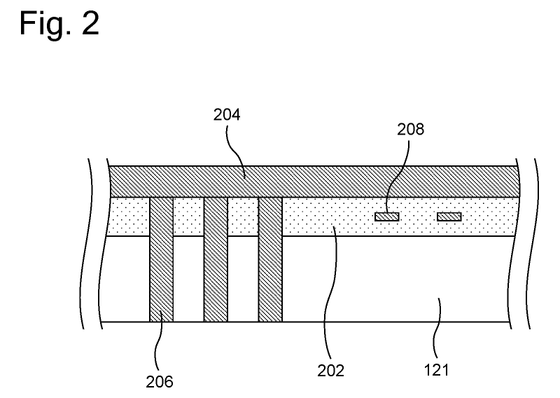

It should be reminded that the matter which influences the output signal of the eddy current sensor 150 is not limited to a film which is exposed on the topmost surface of the substrate 121 (a film formed over the whole topmost surface of the substrate 121) and is an object of polishing. FIG. 2 is a cross-sectional schematic view that shows a structure of an example substrate 121 which is an object to be polished by the substrate polishing apparatus 100. As shown in FIG. 2, a dielectric film (for example, a film comprising SiO₂ or the like) 202 is formed on the whole top surface of the example substrate 121, and, further, a metal film (for example, a film comprising Cu or the like) 204 is formed above the dielectric film 202 to cover it. The metal film 204 is a film which is positioned on the topmost surface of the substrate 121 and is an object of polishing. Further, the substrate 121 may comprise one or multiple through- electrodes 206 which allow electrical conduction between one surface and the other surface of the substrate 121. Further, a metal wire 208 may be embedded in the dielectric film 202 on the substrate 121. When the eddy current sensor 150 passes over a position above or close to a through-electrode 206 or a metal wire 208 such as that explained above, eddy current is also induced in the above metal structure(s), and the output signal of the eddy current sensor 150 is influenced thereby; and, accordingly, the value of the signal changes from that of an output signal of the eddy current sensor 150 obtained when the eddy current sensor 150 has passed over a region on the substrate 121 where no trough-electrode 206 and no metal wire 208 exists. That is, the through-electrode 206 or the metal wire 208 which is a metal structure formed locally in the substrate 121 may become a cause of generation of noise in an output signal of the eddy current sensor 150. It should be reminded that the metal structures are not limited to the through-electrode 206 and the metal wire 208 embedded in the dielectric film 202 which have been explained above, and, in addition thereto, the metal structures may also include a wire exposed on the topmost surface of the substrate 121 and a via, for example.

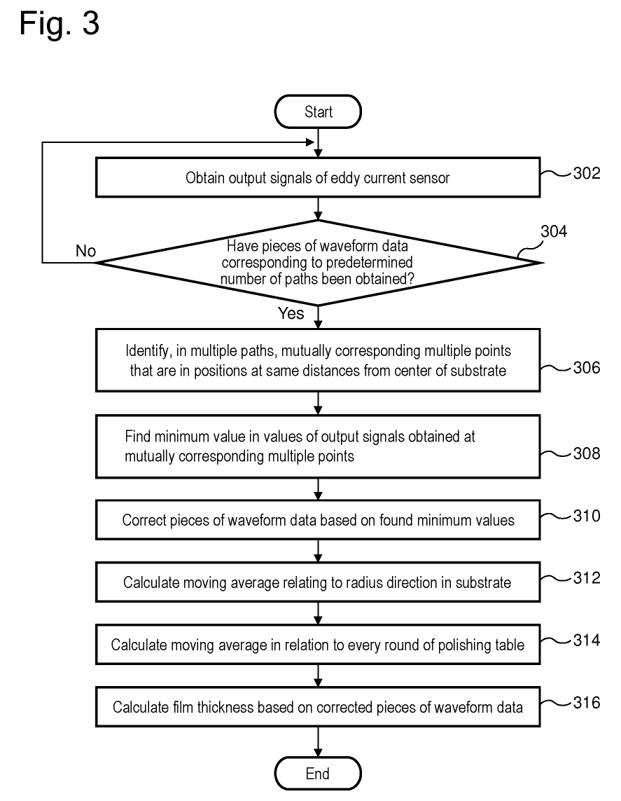

FIG. 3 is a flow chart that shows an algorithm of a method according to an embodiment of the present invention, that can eliminate or reduce noise that is generated due to a local metal structure in the substrate 121 and included in an output signal of the eddy current sensor 150. The process of the present flow chart may be that performed by a processor (for example the processor 142 in the controller 140).

First, in step 302, with respect to the substrate 121, output signals of the eddy current sensor 150 are obtained. Specifically, output signals are obtained from the eddy current sensor 150 while both the polishing head 120, to which the substrate 121 which is the to-be-polished object has been attached, and the polishing table 110 are rotated at respective predetermined rotation speeds. With respect to the substrate 121 (i.e., when viewed from the substrate 121), the eddy current sensor 150 moves on an arc-shaped path that is determined according to the ratio between the rotation speed of the polishing table 110 and the rotation speed of the polishing head 120. During each single rotation of the polishing table 110, the eddy current sensor 150 crosses the surface of the substrate 121 along an ark-shaped path having a predetermined curvature that is determined based on the rotation speeds of the polishing table 110 and the polishing head 120; and, during a next single rotation of the polishing table 110, the eddy current sensor 150 passes a path corresponding to a different arc that is an arc having a curvature that is the same as the curvature in the case of the last single rotation. Accordingly, respective signal values at respective points on the multiple ark-shaped paths are obtained successively from the eddy current sensor 150. In the following description, a series of signal values that is obtained from the eddy current sensor 150 when it has passed one of paths on the substrate 121 will be referred to as a piece of "waveform data" of the output signals of the eddy current sensor 150.

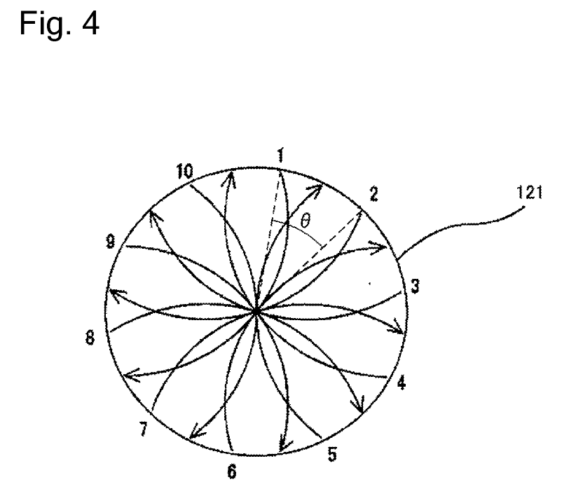

FIG. 4 is a schematic diagram that shows example paths of an eddy current sensor 150 which passes over a substrate 121. In the figure, each arc-shaped curved arrow represents a path on that the eddy current sensor 150 moves, and a direction that the eddy current sensor 150 moves on the path. Further, symbols "1"-"10" in the figure show the order of the paths on that the eddy current sensor 150 moves. The eddy current sensor 150 outputs signal values of points on the paths, respectively, when the polishing table 110 and the polishing head 120 are rotated and the eddy current sensor 150 is accordingly moved along the paths on the surface of the substrate 121 in the order of the paths "1"-"10." In the example in FIG. 4, the angle interval θ between adjacent paths is set to 36 degrees; and, accordingly, after the polishing table 110 rotates ten times, the eddy current sensor 150 moves along the same path that the eddy current sensor 150 had moved along previously (the path next to the path "10" is again the path "1"). The angle interval θ between adjacent paths can be set in an optional manner, by selecting a combination of the rotation speed of the polishing table 110 and the rotation speed of the polishing head 120.

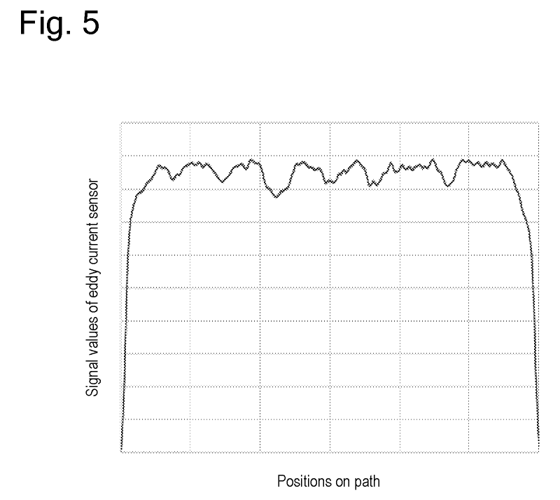

FIG. 5 shows an example of a piece of waveform data obtained in step 302. In a graph in FIG. 5, a horizontal axis represents positions on a path over which the eddy current sensor 150 has passed (i.e., distances from the center of the substrate 121 to the positions of the eddy current sensor 150), and a vertical axis represents values of signals from the eddy current sensor 150. A piece of waveform data corresponds to a single path. Every time when the eddy current sensor 150 passes along a single path as a result of rotation of the polishing table 110 and the polishing head 120, a piece of waveform data such as that shown in FIG. 5 is obtained, and, accordingly, pieces of waveform data are obtained sequentially.

Next, in step 304, the controller 140 makes a judgment as to whether the pieces of waveform data corresponding to a predetermined number of paths have been obtained. The "predetermined number" may be the number of paths that allows that number of paths to cover the substantially whole surface of the substrate 121 uniformly. For example, in the example of paths shown in FIG. 4 explained above, paths can cover the substantially whole surface of the substrate 121 uniformly, if the number of paths is five or more than five (for example, five paths such as paths "1"-"5"). In the above case, a judgment that is to be made in step 304 may be that as to whether pieces of waveform data corresponding to five (or more than five) paths have been obtained. The number of paths that allows the paths to cover the substantially whole surface of the substrate 121 uniformly may change according to the rotation speed of the polishing table 110 and the rotation speed of the polishing head 120. For example, the angle interval θ between adjacent paths is set to 36 degrees in the example shown in FIG. 4 explained above; however, the angle interval θ between adjacent paths becomes that smaller than 36 degrees in the case that difference between the rotation speed of the polishing table 110 and the rotation speed of the polishing head 120 becomes smaller, and, accordingly, a more number of paths than the above number of paths is required to cover the whole surface of the substrate 121 uniformly by the paths. In this regard, although the spatial resolution of film thickness measurement improves since the number of measurement points on the substrate 121 increases in the case that the angle interval θ is narrow, the length of time required to cover the whole surface of the substrate 121 uniformly by the paths increases. On the other hand, although the spatial resolution of film thickness measurement is deteriorated in the case that the angle interval θ is set wide, the whole surface of the substrate 121 can be covered by the paths in a short period of time, and, accordingly, the state of the film thickness on the whole surface of the substrate 121 can be grasped more quickly.

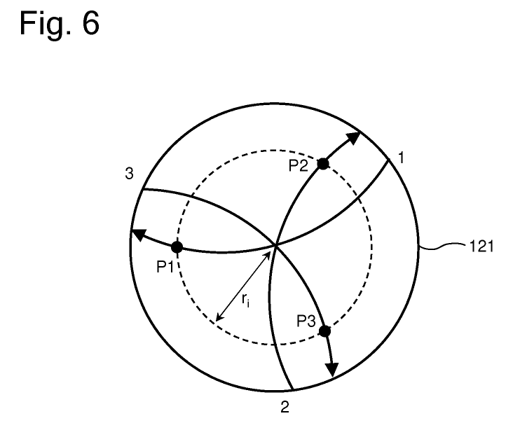

After pieces of waveform data corresponding to a predetermined number of paths have been obtained, the process proceeds to step 306. In step 306, the controller 140 identifies, in multiple paths on the substrate 121, mutually corresponding multiple points that are in positions at same distances from the center of the substrate 121. For example, FIG. 6 shows three paths, along those the eddy current sensor 150 passes, on the substrate 121, i.e., a path "1," a path "2," and a path "3." In this example, a point P1 on the path "1," a point P2 on the path "2," and a point P3 on the path "3" are mutually corresponding points in positions at same distances, specifically, a radius rᵢ, from the center of the substrate 121. In relation to each arbitrarily selected radius rᵢ that extends from the center of the substrate 121, the controller 140 identifies multiple points mutually corresponding to one another, such as those explained above.

It should be reminded that FIG. 6 has been shown for convenience of explanation, and it is obvious that more than three paths may exist on the substrate 121 in an actual case.

Next, in step 308, the controller 140 compares values of output signals of the eddy current sensor 150 obtained at the mutually corresponding multiple points identified in step 306 with one another to find a minimum value in the values. Specifically, in the case that FIG. 6 is referred to again, the controller 140 compares a value of an output signal of the current sensor 150 at the point P1 on the path "1," a value of an output signal of the current sensor 150 at the point P2 on the path "2," and a value of an output signal of the current sensor 150 at the point P3 on the path "3" with one another, and determines a minimum value in the above values. In relation to each of other arbitrarily selected radiuses rᵢ, the controller 140 performs a process similar to that explained above.

Next, in step 310, based on the minimum values found in step 308, the controller 140 corrects the pieces of waveform data. The process for correcting the pieces of waveform data includes application of the minimum values found in step 308 to the respective corresponding points on the pieces of waveform data. As explained above, in step 308, in relation to an arbitrarily selected radius rᵢ that extends from the center of the substrate 121, a minimum value in the values of output signals of the eddy current sensor 150 obtained at multiple points corresponding to the radius rᵢ is determined. That is, in relation to each of various radiuses, a single minimum value outputted from the eddy current sensor 150 is determined. In step 310, correction of each piece of waveform data is performed by replacing signal values of respective points on the piece of waveform data (i.e., values of signals of the eddy current sensor 150 obtained at respective radius positions on the substrate 121) by minimum signal values corresponding to the respective points (i.e., the minimum values found in step 308).

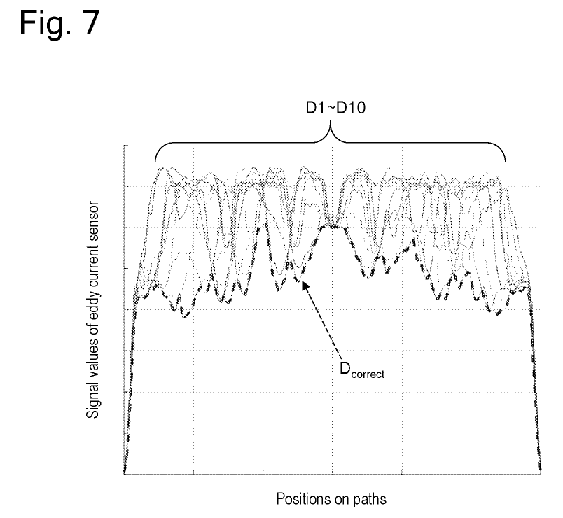

FIG. 7 shows, for explaining a correction process performed in step 310, examples of pieces of waveform data before correction and an example of the piece of waveform data after correction. In FIG. 7, pieces of pre-correction waveform data D1-D10 are represented by solid lines. For example, the pieces of pre-correction waveform data D1-D10 correspond to the paths "1"-"10" in FIG. 4, respectively. In FIG. 7, a piece of post-correction waveform data D_{correct} is represented by a thick broken line that is obtained by tracing only minimum points in the pre-correction waveform data D1-D10.

It is highly likely that multiple peaks included in the pieces of pre-correction waveform data correspond to noise due to a metal structure(s) (a through-electrode 206, a metal wire 208, or the like) locally existing on the surface of or in the inside of the substrate 121. Accordingly, by correcting the pieces of waveform data in accordance with steps 306-310, the noise, that is due to a local metal structure(s) included in the substrate 121 and introduced into output signals of the eddy current sensor 150, can be eliminated or reduced.

Next, in step 312, the controller 140 calculates, with respect to the post-correction waveform data in step 310, a moving average relating to a radius direction in the substrate 121 (i.e., a moving average relating to the horizontal-axis direction in the graph in FIG. 7). The processes in steps 306-312 are repeatedly performed every time when the eddy current sensor 150 has passed a new single path. For example, steps 306-312 are performed when the eddy current sensor 150 has passed ten paths "1"-"10;" and, after the eddy current sensor 150 has passed the path "1" again after passing the path "10," steps 306-312 are performed in a similar manner by using pieces of waveform data corresponding to the most recent ten paths (i.e., ten paths including the paths "2"-"10" and the path "1" passed after passing the path "10"). Processing performed after that is similar to the processing explained above.

Next, in step 314, the controller 140 calculates a moving average with respect to multiple pieces of waveform data; wherein, with respect to the multiple pieces of waveform data herein, a calculation process has been applied to them (i.e., a moving average relating to a radius direction has been calculated) in step 312 every time when the eddy current sensor 150 has passed a new single path, so that calculation processes relating to the multiple pieces of waveform data have been performed serially. For example, a moving average with respect to multiple pieces of waveform data, that include a piece of waveform data obtained by applying processes in steps 306-312 to first waveform data D1-D10, a piece of waveform data obtained by applying processes in steps 306-312 to next waveform data D2-D11, and a piece of waveform data obtained by applying processes in steps 306-312 to next next waveform data D3-D12, may be calculated. By performing moving average processes in steps 312 and 314, fine noise existing in waveform data of output signals of the eddy current sensor 150 can be eliminated.

Next, in step 316, the controller 140 calculates thickness of the film on the surface of the substrate 121, based on the waveform data obtained as a result of the process in step 314.

By adopting the above processes, accurate film thickness distribution data in a substrate radius direction, that is not influenced by a through-electrode 206, a metal wire 208, or the like in/on the substrate 121, can be obtained. Based on film thickness distribution data obtained during polishing of the substate 121, the controller 140 may be able to accurately determine an end point of polishing. Also, based on the film thickness distribution data obtained during polishing of the substate 121, the controller 140 may increase/decrease internal pressure of the air bag 122 to increase polishing pressure applied to a region where the film thickness is large (i.e., a region where progress in polishing is slow) and decrease polishing pressure applied to a region where the film thickness is small (i.e., a region where progress in polishing is fast). By performing the above controlling, the thickness of the film on the substrate 121 can be made uniform.

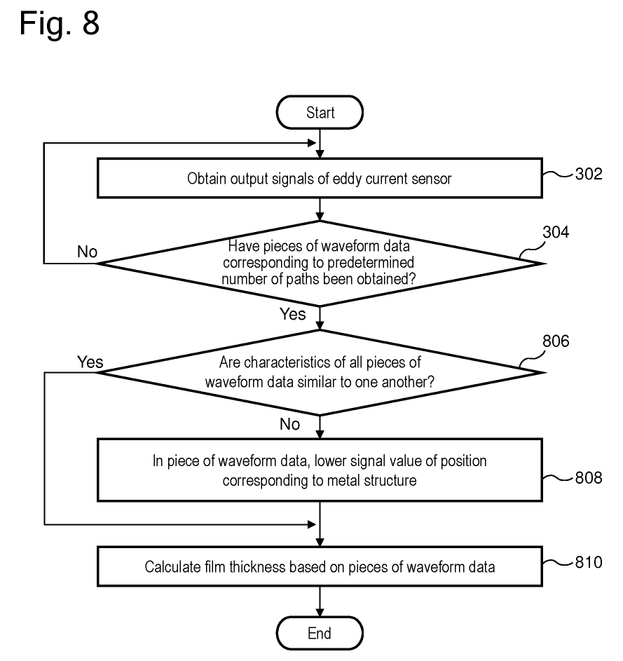

FIG. 8 is a flow chart that shows an algorithm of a film thickness calculating method according to a different embodiment of the present invention that can eliminate or reduce noise that is generated due to a local metal structure in the substrate 121 and included in an output signal of the eddy current sensor 150. The process of the present flow chart may be that performed by a processor (for example the processor 142 in the controller 140). Steps 302 and 304 in the algorithm according to the present embodiment are the same as those in the embodiment in FIG. 3 explained above, and, accordingly, repeated explanation thereof will be omitted herein. In this regard, in step 304 in the present embodiment, the "predetermined number" may be "at least three."

In step 806 that follows step 304, the controller 140 makes a judgment as to whether a metal structure exists on a path on the substrate, based on comparison between the degrees of similarity with respect to multiple pieces of waveform data obtained in step 304. With respect to multiple pieces of waveform data, in the case that the degrees of similarity of a predetermined number (for example, more than half) of pieces of waveform data are high and the degrees of similarity of remaining pieces of waveform data are low, the controller may judge that a metal structure(s) exists on the paths corresponding to the remaining pieces of waveform data.

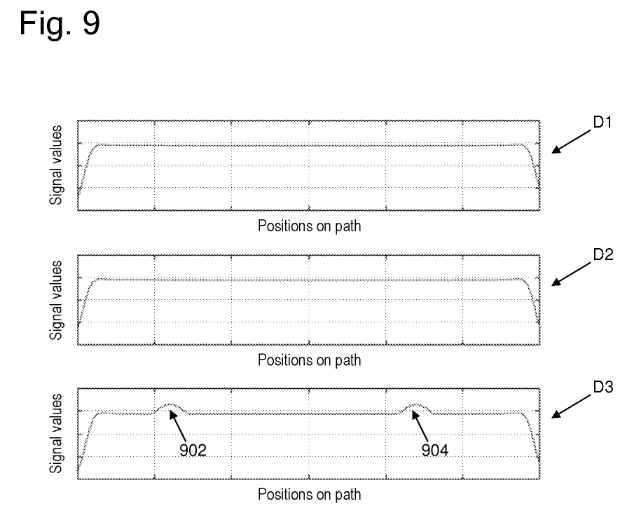

For example, it is supposed that three pieces of waveform data D1, D2, and D3 such as those shown in FIG. 9 were obtained in step 304. For example, the pieces of waveform data D1, D2, and D3 may be those corresponding to the paths "1," "2," and "3," respectively. In this example, each of the pieces of waveform data D1 and D2 has a relatively flat shape in the substantially whole part of the path. On the other hand, the piece of waveform data D3 has two peaks 902 and 904 in the middle part of the path. It is highly likely that these peaks are created due to noise caused by a metal structure(s) (a through-electrode 206, a metal wire 208, or the like) locally existing on the surface of or in the inside of the substrate 121. Accordingly, comparison between shapes of the pieces of waveform data D1, D2, and D3 is performed, and, based on result of comparison that shows that the piece of waveform data D3 has a shape having characteristics different from those of the shapes of the pieces of waveform data D1 and D2, it is possible to judge that a metal structure(s) exists in the positions that correspond to the above peaks and are included in the path "3" in the multiple paths along that the eddy current sensor 150 has passed. As explained above, by performing the process for comparison between the degrees of similarity of multiple pieces of waveform data and thereafter performing the process for "majority decision," a path on that a metal structure exists can be found. In this regard, it can be judged that no path crossing a metal structure exists, in the case that each piece of waveform data has characteristics similar to those of other pieces of waveform data in all pieces of waveform data.

It should be reminded that the process for comparison between the degrees of similarity of multiple pieces of waveform data in step 806 can be realized by using a method in a variety of methods. For example, it may be possible to calculate correlation coefficients of multiple pieces of waveform data D1, D2, D3, and so on, and judge a piece of waveform data having a low correlation coefficient as that having a low degree of similarity. Further, for example, it may be possible to detect a peak part(s) (for example, the peaks 902 and 904 in FIG. 9) in multiple pieces of waveform data D1, D2, D3, and so on, by adopting machine learning that uses clustering such as k-means clustering, One Class SVM (Support Vector Machine), or the like. Further, it may be possible to calculate an average curve of multiple pieces of waveform data by calculating, with respect to each point in a piece of waveform data and other points corresponding to the above point in other pieces of waveform data, an average value of these points, and find, from multiple pieces of waveform data and based on deviation of each of pieces of waveform data from the average curve, a piece(s) of waveform data having characteristics different from those of other pieces of waveform data.

If it is judged in step 806 that a metal structure exists on a path of the eddy current sensor 150, the process proceeds to step 808. In step 808, the controller 140 corrects a piece of waveform data, that corresponds to the path that has been judged as a path on that a metal structure exists, to lower a signal value of a position where the metal structure exists.

Specifically, in the case that FIG. 9 is referred to again, the piece of waveform data D3 is corrected by reducing the values of the two peaks 902 and 904 and the values of positions near the peaks. In this regard, correction may be that comprising a process for changing each of the signal value of each peak and the signal values of positions near the peak in a piece of pre-correction waveform data to a predetermined value smaller than the peak value of the peak. For example, the predetermined value may be a value obtained by multiplying a peak value of each peak by a predetermined attenuation rate (for example, 30%).

As explained in relation to the embodiment in FIG. 3, it is highly likely that a peak included in a piece of waveform data is noise due to a metal structure(s) (a through-electrode 206, a metal wire 208, or the like) locally existing on the surface of or in the inside of the substrate 121. Accordingly, by correcting a piece(s) of waveform data in steps 806 and 808, the noise, that is due to a local metal structure(s) included in the substrate 121 and introduced into output signals of the eddy current sensor 150, can be eliminated or reduced.

Next, in step 810, the controller 140 calculates thickness of the film on the surface of the substrate 121, based on the piece(s) of waveform data corrected in step 808 and pieces of waveform data other than the corrected piece(s) of waveform data. For example, in the example in FIG. 9 explained above, a piece of average waveform data may be created by averaging a corrected piece of waveform data, that was created by applying the process in step 808 to the piece of waveform data D3 corresponding to the path on that a metal structure exists, and the (uncorrected original) pieces of waveform data D1 and D2 that correspond to the paths on those no metal structure exist; and thickness of the film on the surface of the substrate 121 may be calculated by using the piece of average waveform data.

In the above description, embodiments of the present invention have been explained based on some examples; and, in this regard, the above explained embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

### REFERENCE SIGNS LIST

100 Substrate polishing apparatus

110 Polishing table

111 Polishing pad

120 Polishing head

121 Substrate

122 Air bag

130 Liquid supplying mechanism

140 Controller

141 Storage device

142 Processor

143 Input/output device

150 Eddy current sensor

202 Dielectric film

204 Metal film

206 Through-electrode

208 Metal wire

What is claimed is:

1. A substrate polishing apparatus comprising:
a polishing table which is provided with an eddy current sensor and constructed to be able to rotate,
a polishing head which is arranged to face the polishing table, constructed to be able to rotate, and constructed to allow a substrate to be attached to a surface facing the polishing table, and
a controller; wherein
the controller is constructed to
obtain pieces of waveform data of output signals of the eddy current sensor when the eddy current sensor has passed multiple paths on the substrate,
identify, in the multiple paths on the substrate, mutually corresponding multiple points that are in positions at same distances from the center of the substrate,
compare values of the output signals of the eddy current sensor obtained at the identified multiple points to thereby find a minimum value,
correct the pieces of waveform data based on the found minimum values, and
calculate thickness of a film on a surface of the substrate, based on the corrected pieces of waveform data.

2. The substrate polishing apparatus as recited in claim 1, wherein the process to correct the pieces of waveform data comprises a process to apply the respective found minimum values to respective points in the pieces of waveform data.

3. The substrate polishing apparatus as recited in claim 1, wherein each of the pieces of waveform data is a piece of data comprising a series of output signals obtained from the eddy current sensor when the eddy current sensor passed, in relation to rotation of the polishing table and the polishing head, a path on the substrate.

4. The substrate polishing apparatus as recited in claim 1, wherein the substrate is that having one or multiple metal structures locally existing on the surface of or in the inside of the substrate.

5. The substrate polishing apparatus as recited in claim 4, wherein the metal structure is a trough-electrode or a metal wire formed on or in the substrate.

6. The substrate polishing apparatus as recited in claim 1, further comprising
an air bag which is able to adjust polishing pressure applied to the substrate; wherein
the controller is further constructed to control internal pressure of the air bag, based on the calculated thickness of the film on the substrate.

7. A substrate polishing apparatus comprising:
a polishing table which is provided with an eddy current sensor and constructed to be able to rotate,
a polishing head which is arranged to face the polishing table, constructed to be able to rotate, and constructed to allow a substrate to be attached to a surface facing the polishing table, and
a controller; wherein
the controller is constructed to
obtain multiple pieces of waveform data representing output signals of the eddy current sensor when the eddy current sensor has passed multiple paths on the substrate, wherein each piece of waveform data corresponds to a single path,
make a judgment as to whether a metal structure exists on a path on the substrate, based of comparison between degrees of similarity of the multiple pieces of waveform data,
correct a piece of waveform data corresponding to the path on that the metal structure exists, to lower a signal value of the position that has been judged as a position where the metal structure exists, and
calculate thickness of a film on a surface of the substrate, based on the corrected piece of waveform data and the pieces of waveform data other than the corrected piece of waveform data.

8. The substrate polishing apparatus as recited in claim 7, wherein the process to make a judgment comprises a process to judge, in the case that the degrees of similarity of a predetermined number of pieces of waveform data in the multiple pieces of waveform data are high and the degrees of similarity of remaining pieces of waveform data in the multiple pieces of waveform data are low, that metal structures exist on the paths corresponding to the remaining pieces of waveform data.

9. The substrate polishing apparatus as recited in claim 8, wherein the predetermined number is more than half of the total number.

10. A film thickness calculating method in a substrate polishing apparatus, wherein
the substrate polishing apparatus comprises
a polishing table which is provided with an eddy current sensor and constructed to be able to rotate, and
a polishing head which is arranged to face the polishing table, constructed to be able to rotate, and constructed to allow a substrate to be attached to a surface facing the polishing table; and
the method comprises steps for:
obtaining pieces of waveform data of output signals of the eddy current sensor when the eddy current sensor has passed multiple paths on the substrate,
identifying, in the multiple paths on the substrate, mutually corresponding multiple points that are in positions at same distances from the center of the substrate,
comparing values of the output signals of the eddy current sensor obtained at the identified multiple points to thereby find a minimum value,
correcting the pieces of waveform data based on the found minimum values, and
calculating thickness of a film on a surface of the substrate, based on the corrected pieces of waveform data.
